(19) United States
(12) Patent Application Publication
(10) Pub. No.: US 2009/0065949 A1
(43) Pub. Date: Mar. 12, 2009

(54) Semiconductor package and semiconductor module having the same

(75) Inventors: Choong-Bin Yim, Seongnam-si (KR); Tae-Je Cho, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/228,500

(22) Filed: Aug. 13, 2008

(30) Foreign Application Priority Data
Sep. 12, 2007 (KR) 10-2007-0092462

(51) Int. Cl. H01L 23/52

(52) U.S. Cl. 257/777; 257/E23.129

(57) ABSTRACT

A semiconductor package can include a semiconductor chip, an insulating substrate, first bond fingers, and pads. The insulating substrate can be attached to edge portions of the semiconductor chip. The first bond fingers can be arranged on edge portions of an upper surface of the insulating substrate. Further, the first bond fingers can be electrically connected to the semiconductor chip. The pads can be arranged on a central portion of the upper surface of the insulating substrate. Further, the pads can be electrically connected to the first bond fingers. Thus, types of stackable devices that can be mounted on or in the semiconductor package need not be restricted.

### PRIORITY STATEMENT

This application claims priority under 35 U.S.C. §119 to Korean Patent Application No. 10-2007-0092462 filed on Sep. 12, 2007 in the Korean Intellectual Property Office (KIPO), the contents of which are herein incorporated by reference in their entirety.

### BACKGROUND

1. Field of the Invention

The present invention relates to a semiconductor package and a semiconductor module having the same. More particularly, the present invention relates to a semiconductor package having a plurality of pads, and a semiconductor module having the semiconductor package.

2. Description of the Related Art

Generally, various semiconductor fabricating processes can be performed on a wafer to form a plurality of semiconductor chips. In order to mount the semiconductor chips on a printed circuit board (PCB), a packaging process can be performed on the wafer to form semiconductor packages.

To increase storage capacity of the semiconductor package, a stacked semiconductor package, including semiconductor packages sequentially stacked, can be widely studied. Further, to reduce a thickness of the stacked semiconductor package, the semiconductor package can be received in a cavity of a circuit substrate.

However, external terminals, such as pads, may not be formed on an upper surface of a conventional semiconductor package in the cavity. Thus, lands arranged along a periphery of the circuit substrate can serve as the external terminals. As a result, a useful bus width of the stacked semiconductor package can be very narrow.

Further, the conventional semiconductor package can be stacked only at an edge portion of the circuit pattern. Therefore, types of devices, such as the semiconductor package, that can be configured to be stacked on the circuit pattern can be significantly restricted.

### SUMMARY

In accordance with aspects of the present invention, a semiconductor package having a stackable structure with a wide bus width can be provided.

Also in accordance with aspects of the present invention, a semiconductor module including the above-mentioned semiconductor package can be provided.

A semiconductor package in accordance with one aspect of the present invention includes a semiconductor chip, an insulating substrate, first bond fingers, and pads. The insulating substrate is coupled to edge portions of the semiconductor chip. The first bond fingers are arranged on edge portions of an upper surface of the insulating substrate. Further, the first bond fingers are electrically connected to the semiconductor chip. The pads are arranged on a central portion of the upper surface of the insulating substrate, and are electrically connected to the first bond fingers.

Each of the first bond fingers can have a rectangular shape and the first bond fingers can be spaced apart from each other by a substantially regular interval.

The pads can be spaced apart from each other by substantially the same interval in lengthwise and breadthwise directions.

Each of the pads can have a circular shape.

The semiconductor chip and the first bond fingers can be electrically connected with each other via conductive wires.

A molding member can be formed under the semiconductor chip and the insulating substrate to cover the conductive wires.

The semiconductor package can further include an auxiliary insulating substrate coupled to a lower surface of the semiconductor chip, and auxiliary bond fingers arranged on a lower surface of the auxiliary insulating substrate. The auxiliary bond fingers can be electrically connected to the first bond fingers.

Further, plugs can be built into the auxiliary insulating substrate to electrically connect the auxiliary bond fingers with the first bond fingers.

The semiconductor package can also comprise conductive members mounted on the pads.

A semiconductor module in accordance with another aspect of the present invention includes a circuit substrate and a semiconductor package. The circuit substrate has a cavity and a circuit pattern. The semiconductor package is arranged in the cavity. The semiconductor package includes first bond fingers and pads. The first bond fingers are electrically connected to the circuit pattern. The pads are electrically connected to the first bond fingers.

The cavity can be formed at a central portion of an upper surface of the circuit substrate.

The circuit pattern can include second bond fingers, first lands, and second lands. The second bond fingers can be arranged on the circuit substrate. Further, the second bond fingers can be electrically connected to the first bond fingers. The first lands can be arranged on an upper surface of the circuit substrate. Further, the first lands can be electrically connected to the second bond fingers. The second lands can be arranged on a lower surface of the circuit substrate. Further, the second lands can be electrically connected to the second bond fingers.

The second bond fingers can be arranged on the upper surface of the circuit substrate adjacent to the cavity.

In this case, the first bond fingers and the second bond fingers can be electrically connected with each other via conductive wires.

Further, a molding member can cover the conductive wires.

The semiconductor module can include first conductive members mounted on the first lands and the pads.

The semiconductor module can include a second semiconductor package stacked on the first conductive members

The second bond fingers can be arranged at edge portions of a bottom surface of the cavity. In this case, the second bond fingers can make direct contact with the first bond fingers.

The semiconductor package can include a semiconductor chip, an insulating substrate, first bond fingers, and pads. The insulating substrate can be attached to an upper surface of the semiconductor chip. The first bond fingers can be arranged on the insulating substrate. Further, the first bond fingers can be electrically connected between the semiconductor chip and the circuit pattern. The pads can be arranged on a central portion of the upper surface of the insulating substrate. Further, the pads can be electrically connected to the first bond fingers.

The semiconductor package can further include an auxiliary insulating substrate attached to a lower surface of the semiconductor chip, and auxiliary bond fingers arranged on edge portions of a lower surface of the auxiliary insulating substrate. The auxiliary bond fingers can be electrically connected to the first bond fingers. Further, the auxiliary bond fingers can make direct contact with the circuit pattern.

In accordance with another aspect of the present invention, a semiconductor module is provided that comprises a circuit substrate having a cavity and a circuit pattern, and a semiconductor package arranged in the cavity. The semiconductor package includes a semiconductor chip, an insulating substrate attached to the semiconductor chip, first bond fingers arranged on edge portions of an upper surface of the insulating substrate. The first bond fingers electrically connect the semiconductor chip with the circuit pattern. The semiconductor package also includes pads arranged on a central portion of the upper surface of the insulating substrate. The pads electrically connect to the first bond fingers. The circuit pattern includes second bond fingers arranged on the circuit substrate, the second bond fingers are electrically connected to the first bond fingers. The circuit pattern also includes first lands arranged on an upper surface of the circuit substrate, and the first lands are electrically connected to the second bond fingers. And second lands are arranged on a lower surface of the circuit substrate, the second lands are electrically connected to the second bond fingers.

The semiconductor module can further include conductive wires electrically connecting the first bond fingers to the second bond fingers and a molding member covering the conductive wires.

In accordance with yet another aspect of the present invention, provided is a semiconductor module comprising a circuit substrate having a cavity and a circuit pattern, and a semiconductor package arranged in the cavity. The semiconductor package includes a semiconductor chip and an insulating substrate attached to the semiconductor chip. First bond fingers are arranged on edge portions of an upper surface of the insulating substrate and electrically connect the semiconductor chip with the circuit pattern. Pads are arranged on a central portion of the upper surface of the insulating substrate; the pads are electrically connected to the first bond fingers. An auxiliary insulating substrate is attached to a lower surface of the semiconductor chip and auxiliary bond fingers are arranged on edge portions of a lower surface of the auxiliary insulating substrate. The auxiliary bond fingers electrically connect to the first bond fingers and make direct contact with the second bond fingers. The circuit pattern includes second bond fingers arranged on the circuit substrate; the second bond fingers electrically connect to the first bond fingers. The circuit pattern also includes first lands arranged on an upper surface of the circuit substrate, where the first lands electrically connect to the second bond fingers. And second lands are arranged on a lower surface of the circuit substrate, the second lands are electrically connected to the second bond fingers.

According to the present invention, the pads can be arranged on the upper surface of the insulating substrate. Thus, the lands of the circuit substrate and the pads of the semiconductor package can be used for external terminals. As a result, the semiconductor module can have a wider bus width. Further, types of stackable devices need not be restricted.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the invention. In the drawings:

FIG. 1 is a plan view illustrating an example embodiment of a semiconductor package in accordance with aspects of the present invention;

FIG. 2 is a cross-sectional view taken along a line II-II′ in FIG. 1;

FIG. 3 is a plan view illustrating another example embodiment of a semiconductor package in accordance with aspects of the present invention;

FIG. 4 is a plan view illustrating an example embodiment of a semiconductor module in accordance with aspects of the present invention;

FIG. 5 is a cross-sectional view taken along a line V-V′ in FIG. 4;

FIG. 6 is a plan view illustrating an example embodiment of a circuit substrate of the semiconductor module in FIG. 4;

FIG. 7 is a plan view illustrating an example embodiment of conductive wires for electrically connecting the circuit substrate to the semiconductor package in FIG. 6;

FIG. 8 is a plan view illustrating an example embodiment of a semiconductor module in accordance with aspects of the present invention;

FIG. 9 is a cross-sectional view taken along a line IX-IX′ in FIG. 8;

FIG. 10 is a plan view illustrating an example embodiment of a circuit substrate of the semiconductor module in FIG. 8;

FIG. 11 is a cross-sectional view illustrating another example embodiment of a semiconductor module in accordance with aspects of the present invention; and

FIG. 12 is a cross-sectional view illustrating yet another example embodiment of a semiconductor module in accordance with aspects of the present invention.

### DETAILED DESCRIPTION OF PREFERRED EMBODIMENTS

Aspects of the present invention are described more fully hereinafter with reference to the accompanying drawings. The present invention can, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers can be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device can be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments in accordance with aspects of the invention are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, the example embodiments provided should not be construed as limited to the particular shapes of regions illustrated herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation can result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Hereinafter, the example embodiments in accordance with the present invention will be explained in detail with reference to the accompanying drawings.

Semiconductor Package

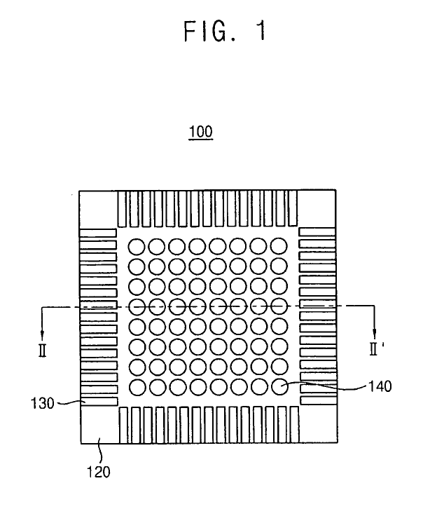

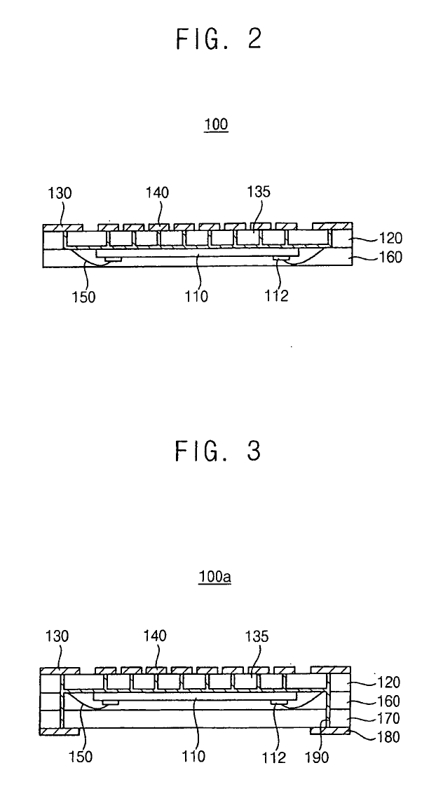

FIG. 1 is a plan view illustrating an example embodiment of a semiconductor package in accordance with aspects of the present invention, and FIG. 2 is a cross-sectional view taken along a line II-II′ in FIG. 1.

Referring to FIGS. 1 and 2, a semiconductor package 100 of this example embodiment can include a semiconductor chip 110, an insulating substrate 120, first bond fingers 130, pads 140, conductive wires 150 and a molding member 160.

The semiconductor chip 110 can have bonding pads 112. Further, the semiconductor chip 110 can have a rectangular shape, although the present invention is not limited to a rectangular shape. In this example embodiment, the bonding pads 112 of the semiconductor chip 110 can be oriented toward a downward direction. That is, the bonding pads 112 can be arranged on a lower surface of the semiconductor chip 110.

The insulating substrate 120 can be attached to an upper surface of the semiconductor chip 110. In this example embodiment, the insulating substrate 120 can have a rectangular shape larger than that of the semiconductor chip 110. Thus, edge portions of the insulating substrate 120 can be protruded beyond the edges of the semiconductor chip 110.

The first bond fingers 130 can be arranged on edge portions of an upper surface of the insulating substrate 120. In this example embodiment, each of the first bond fingers 130 can have a long rectangular shape (e.g., see FIG. 1). Further, the first bond fingers 130 can be arranged spaced apart from each other by a substantially regular interval, e.g., substantially the same interval. The first bond fingers 130 can be electrically connected to a circuit pattern (not shown) built into a circuit substrate (not shown) via conductive members (not shown), such as conductive wires, as would be understood by those skilled in the art.

The pads 140 can be arranged on a central portion of the upper surface of the insulating substrate 120. The pads 140 can be electrically connected to the first bond fingers 130. In this example embodiment, the pads 140 and the first bond fingers 130 can be electrically connected with each other via plugs 135 formed or arranged in the insulating substrate 120. Alternatively, the pads 140 and the first bond fingers 130 can be electrically connected with each other via conductive traces (not shown) arranged on the upper surface of insulating substrate 120. Further, the pads 140 can be arranged spaced apart from each other by a substantially regular interval in lengthwise and breadthwise directions. In this example embodiment, the pads 140 can have a circular shape, for example.

Other semiconductor devices (not shown), such as other semiconductor packages, a transistor, a diode, etc., can be mounted on the pads 140. Here, since the pads 140 can be arranged on the central portion of the upper surface of the insulating substrate 120, other semiconductor devices can be stacked on the insulating substrate 120 regardless of types and sizes of such semiconductor devices. Further, the pads 140 can serve to effectively widen a bus width of the semiconductor package 100.

The conductive wires 150 can be electrically connected between the bonding pads 112 of the semiconductor chip 110 and the first bond fingers 130. In this example embodiment, the conductive wires 150 can include a metal, such as gold, aluminum, and the like. Although, any of a variety of known conductive materials or compositions could suffice.

The molding member 160 can be formed under the insulating substrate 120 and the semiconductor chip 110 to cover the conductive wires 150. That is, the molding member 160 can prevent the conductive wires 150 from being exposed, which can protect the conductive wires 150 from external impacts. Thus, the conductive wires 150 are not susceptible to being cut, owing to the protection offered by the molding member 160. In this example embodiment, the molding member 160 can include epoxy resin, as an example. Other non-conductive materials could alternatively be used, preferably having some shock absorption qualities.

According to this example embodiment, the pads can be arranged on the upper surface of the insulating substrate. Thus, the semiconductor package can effectively have a wide bus width. Further, types and sizes of devices that can be configured to be mounted on the pads are not substantially restricted, because the semiconductor package offers a substantial improvement in mounting flexibility.

FIG. 3 is a plan view illustrating another embodiment of a semiconductor package in accordance with aspects of the present invention.

A semiconductor package 100a of this example embodiment can include elements substantially the same as those of the semiconductor package 100 in FIG. 1 except for an auxiliary insulating substrate, auxiliary bond fingers and plugs. Thus, the same reference numerals refer to the same elements and any further illustrations with respect to the same elements are omitted herein for brevity.

Referring to FIG. 3, the semiconductor package 100a of this example embodiment can further include an auxiliary insulation substrate 170, auxiliary bond fingers 180 and plugs 190.

The auxiliary insulating substrate 170 can be placed under the lower surface of the semiconductor chip 110. The auxiliary insulating substrate 170 can be attached to a lower surface of the molding member 160. In this example embodiment, the auxiliary insulating substrate 170 can be formed from a material and have a size substantially the same as those of the insulating substrate 120. Further, via holes can be formed through edge portions of the auxiliary insulating substrate 170.

The auxiliary bond fingers 180 can be arranged on edge portions of a lower surface of the auxiliary insulating substrate 170. In this example embodiment, the auxiliary bond fingers 180 can have a material and a size substantially the same as those of the first bond fingers 130. Here, the auxiliary bond fingers 180 can directly make contact with the circuit pattern of the circuit substrate.

The via holes can be filled with the plugs 190. Thus, the first bond fingers 130 can be electrically connected to the auxiliary bond fingers 180 via the plugs 190. In this example embodiment, the plugs 190 can include a material substantially the same as that of the auxiliary bond fingers 180.

According to this example embodiment, the auxiliary bond fingers 180 can be arranged on the lower surface of the auxiliary insulating substrate 170, so that the semiconductor package can be directly connected to the circuit substrate without additional conductive members.

Semiconductor Module

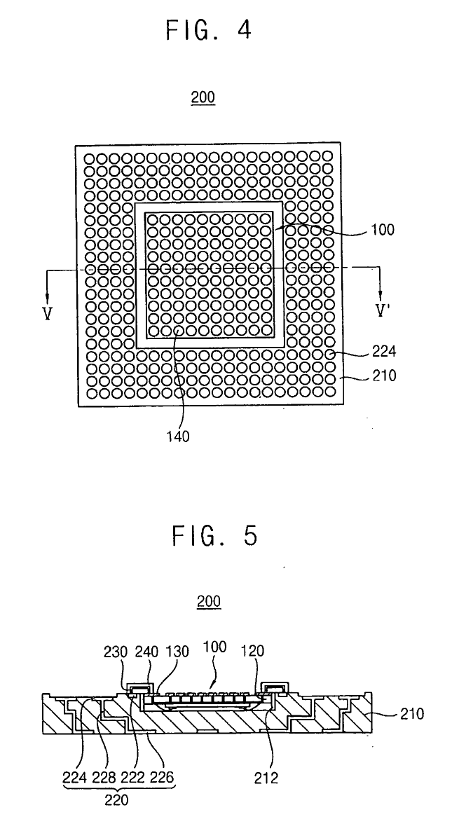

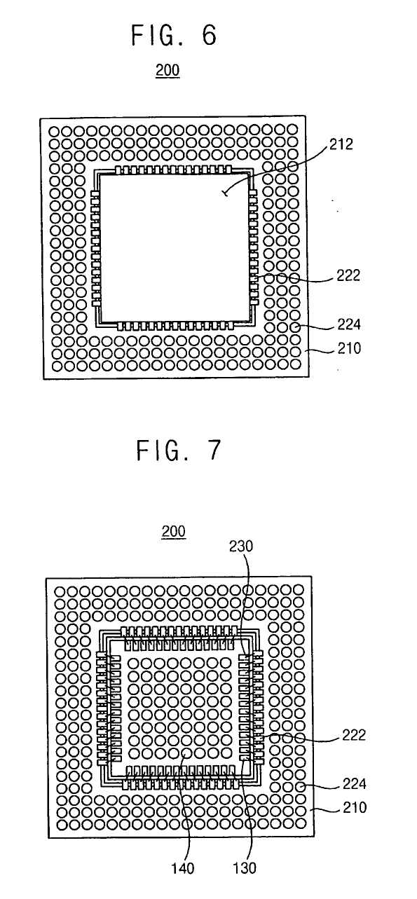

FIG. 4 is a plan view illustrating an embodiment of a semiconductor module in accordance with aspects of the present invention, FIG. 5 is a cross-sectional view taken along a line V-V′ in FIG. 4, FIG. 6 is a plan view illustrating an embodiment of a circuit substrate of the semiconductor module in FIG. 4, and FIG. 7 is a plan view illustrating an embodiment of conductive wires for electrically connecting the circuit substrate to the semiconductor package in FIG. 6.

Referring to FIGS. 4 to 7, a semiconductor module 200 of this example embodiment can include a semiconductor package 100, a circuit substrate 210, conductive wires 230 and a molding member 240.

Here, the semiconductor package 100 can include elements substantially the same as those of the semiconductor package in FIG. 1. Thus, the same reference numerals refer to the same elements and any further illustrations with respect to the same elements are omitted herein for brevity.

The circuit substrate 210 can have a cavity 212. The cavity 212 can be formed at a central portion of an upper surface of the circuit substrate 210. In this example embodiment, the cavity 212 can have a rectangular shape, but other shapes could be used in other embodiments. Thus, the circuit substrate 210 can have a rectangular annular upper surface. Further, the cavity 212 can have a depth substantially equal to or greater than a thickness of the semiconductor package 100. The semiconductor package 100 is arranged in the cavity 212 and is not protruded from the upper surface of the circuit substrate 210. Furthermore, the cavity 212 can have a size slightly greater than that of the semiconductor package 100. As a result, a rectangular annular space can be formed between the semiconductor package 100 and inner surfaces of the cavity 212, in this embodiment.

A circuit pattern 220 can be built into the circuit substrate 210. The circuit pattern 220 can include second bond fingers 222, first lands 224, second lands 226 and plugs 228.

In this example embodiment, the second bond fingers 222 can be arranged on the upper surface of the circuit substrate 210 adjacent to the cavity 212. The second bond fingers 220 can be electrically connected to the first bond fingers 130 via the conductive wires 230. The second bond fingers 220 can be made of a material and have a size substantially the same as those of the first bond fingers 130.

Here, the conductive wires 230 can be protruded above the upper surfaces of the circuit substrate 210 and the insulating substrate 120. Therefore, to cover the conductive wires 230 with the molding member 240, the molding member 240 can have a rectangular annular shape and also can be protruded above the upper surfaces of the circuit substrate 210 and the insulating substrate 120. The molding member 240 can also be configured to fill up the rectangular annular space formed between the semiconductor package 100 and inner surfaces of the cavity 212.

The first lands 224 can be arranged on the upper surface of the circuit substrate 210. The first lands 224 can be electrically connected to the second bond fingers 222, in any of a variety of known manners (e.g., wires, circuit patterns, etc.). In this example embodiment, the first lands 224 can have a size and are made of a material substantially the same as those of the pads 140. Further, the first lands 224 can be arranged spaced apart from each other in lengthwise and widthwise directions by a substantially regular interval that is substantially the same as that formed between the pads 140. Thus, the first lands 224 and the pads 140 can be arranged spaced apart from each other by the same interval in the lengthwise and breadthwise directions to form a lattice shape. As a result, other devices can be mounted on the first lands 224 and the pads 140 regardless of sizes and types thereof.

The second lands 226 can be arranged on the lower surface of the circuit substrate 210. The second lands 226 can also be electrically connected to the second bond fingers 222. Further, the plugs 228 can fill up via holes vertically formed through the circuit substrate 210. Thus, the second lands 226 can be electrically connected to the first lands 224 via the plugs 228. As a result, the second lands can be electrically connected to the second bond fingers through plugs 228 and first lands 224.

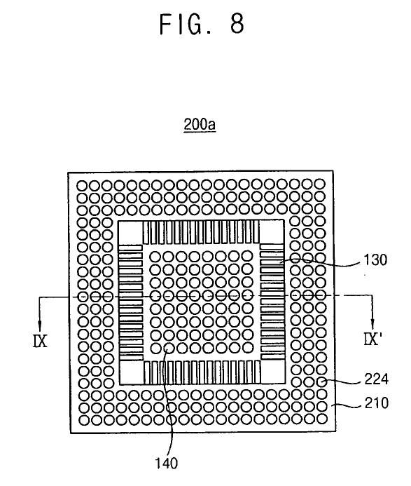

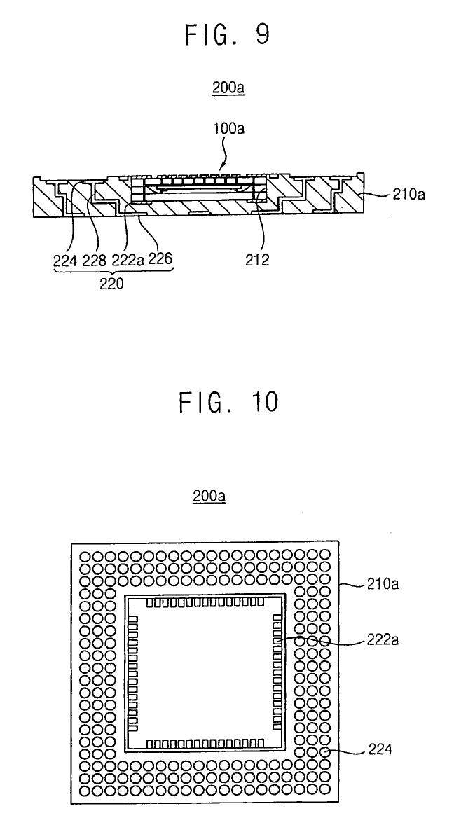

FIG. 8 is a plan view illustrating another embodiment of a semiconductor module in accordance with aspects of the present invention, FIG. 9 is a cross-sectional view taken along a line IX-IX′ in FIG. 8, and FIG. 10 is a plan view illustrating an embodiment of a circuit substrate of the semiconductor module in FIG. 8.

Referring to FIGS. 8 to 10, a semiconductor module 200a of this example embodiment can include a semiconductor package 100a and a circuit substrate 210a.

Here, the semiconductor package 100a can include elements substantially the same as those of the semiconductor package in FIG. 3. Thus, the same reference numerals refer to the same elements and any further illustrations with respect to the same elements are omitted herein for brevity.

Further, the circuit substrate 210a can include elements substantially the same as those of the circuit substrate 210 in FIG. 6, except for second bond fingers 222a. Thus, the same reference numerals refer to the same elements and any further illustrations with respect to the same elements are omitted herein for brevity.

The second bond fingers 222a can be arranged on edge portions of a bottom surface in the cavity 212. The second bond fingers 222a can make direct contact with the auxiliary bond fingers 180 (not shown in FIGS. 8 to 10, but shown in FIG. 3) of the semiconductor package 100a. That is, the semiconductor package 100a and the circuit pattern 210a can be electrically connected with each other by directly contacting the second bond fingers 222a to the auxiliary bond fingers 180 without additional conductive wires. Therefore, the semiconductor module 200a of this example embodiment need not include the conductive wires. Particularly, when the cavity 212 can have a size substantially the same as that of the semiconductor package 100a, a space need not be formed between the semiconductor package 100a and the cavity 212 or a space having a very narrow width can be formed between the semiconductor package 100a and the cavity 212. In this case, it is not necessary to use a molding member.

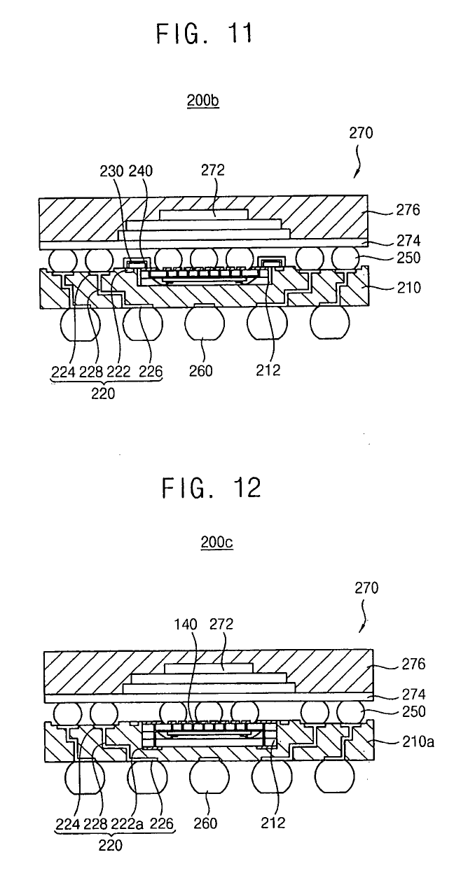

FIG. 11 is a cross-sectional view illustrating another embodiment of a semiconductor module in accordance with aspects of the present invention.

Here, the semiconductor module 200b can include elements substantially the same as those of the semiconductor module 200 in FIG. 5 except for conductive members and a second semiconductor package. Thus, the same reference numerals refer to the same elements and any further illustrations with respect to the same elements are omitted herein for brevity.

Referring to FIG. 11, first conductive members 250 can be mounted on the first lands 224. Second conductive members 260 can be mounted on the second lands 226. In this example embodiment, the first conductive members 250 and the second conductive members 260 can include a solder ball.

The second semiconductor package 270 can be stacked on the first conductive members 250. In this example embodiment, the second semiconductor package 270 can include a plurality of semiconductor chips 272, a substrate 274 attached to lower surfaces of the semiconductor chips 272 and mounted on the second conductive members 250, and a molding member 276 formed on the substrate 274 and the semiconductor chips 272. Here, the semiconductor chips 272 and the substrate 274 can be electrically connected with each other via conductive wires (not shown).

Alternatively, in another embodiment, the semiconductor module 200 in FIG. 5 can be replaced by the semiconductor module 200a in FIG. 9. Further, as mentioned above, since the first lands 224 and the pads 140 can be arranged spaced apart from each other by a substantially regular interval, types and sizes of stacked devices need not be restricted. Thus, semiconductor packages having other structures, such as a semiconductor package having a lead frame, a flip chip package, etc., can be employed in the memory module 200b in place of the second semiconductor package 270. Further, devices such as a transistor, a diode, etc., can be directly mounted on the pads 140 and the first lands 224.

FIG. 12 is a cross-sectional view illustrating another embodiment of a semiconductor module in accordance with aspects of the present invention.

Referring to FIG. 12, a semiconductor module 200c of this example embodiment can include a semiconductor package 100a, a circuit substrate 210a, first conductive members 250, second conductive members 260 and a second semiconductor package 270.

Here, the semiconductor package 100a, the circuit substrate 210a, the first conductive members 250, the second conductive members 260 and the second semiconductor package 270 in the semiconductor module 200c of this example embodiment can be as illustrated in the above example embodiments. Thus, any further illustrations with respect to the semiconductor package 100a, the circuit substrate 210a, the first conductive members 250, the second conductive members 260 and the second semiconductor package 270 in the semiconductor module 200c of this example embodiment can be omitted herein for brevity.

According to some example embodiments of the present invention, the pads 140 can be positioned on the upper surface of the semiconductor package 270. Thus, the lands 224, 226 of the circuit substrate 210a and the pads 140 of the semiconductor package 270 can be used as the external terminals. As a result, the semiconductor module 200c can have a wide bus width. Further, types and sizes of stackable devices need not be restricted.

The foregoing example embodiment are illustrative of aspects of the present invention and are not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of aspects of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A semiconductor package comprising:
a semiconductor chip;
an insulating substrate coupled to the semiconductor chip;
first bond fingers arranged on edge portions of an upper surface of the insulating substrate, the first bond fingers electrically connected to the semiconductor chip; and
pads arranged on a central portion of the upper surface of the insulating substrate, the pads electrically connected to the first bond fingers.

2. The semiconductor package of claim 1, wherein each of the first bond fingers has a rectangular shape and the first bond fingers are spaced apart from each other by a substantially regular interval.

3. The semiconductor package of claim 1, wherein the pads are spaced apart from each other by substantially the same interval in lengthwise and breadthwise directions.

4. The semiconductor package of claim 3, wherein each of the pads has a circular shape.

5. The semiconductor package of claim 1, further comprising conductive wires electrically connecting the semiconductor chip to the first bond fingers.

6. The semiconductor package of claim 5, further comprising a molding member formed under the semiconductor chip and the insulating substrate and covering the conductive wires.

7. The semiconductor package of claim 1, further comprising:
an auxiliary insulating substrate coupled to a lower surface of the semiconductor chip; and
auxiliary bond fingers arranged on edge portions of a lower surface of the auxiliary insulating substrate, the auxiliary bond fingers electrically connected to the first bond fingers.

8. The semiconductor package of claim 7, further comprising plugs built into the auxiliary insulating substrate to electrically connect the auxiliary bond fingers with the first bond fingers.

9. The semiconductor package of claim 1, further comprising conductive members mounted on the pads.

10. A semiconductor module comprising:
a circuit substrate having a cavity and a circuit pattern; and
a semiconductor package arranged in the cavity, the semiconductor package including first bond fingers electrically connected to the semiconductor chip, and pads electrically connected to the first bond fingers.

11. The semiconductor module of claim 10, wherein the cavity is formed at a central portion of an upper surface of the circuit substrate.

12. The semiconductor module of claim 10, wherein the circuit pattern comprises:
second bond fingers arranged on the circuit substrate, the second bond fingers electrically connected to the first bond fingers;
first lands arranged on an upper surface of the circuit substrate, the first lands electrically connected to the second bond fingers; and
second lands arranged on a lower surface of the circuit substrate, the second lands electrically connected to the second bond fingers.

13. The semiconductor module of claim 12, wherein the second bond fingers are arranged on the upper surface of the circuit substrate adjacent to the cavity.

14. The semiconductor module of claim 13, further comprising conductive wires electrically connecting the first bond fingers to the second bond fingers.

15. The semiconductor module of claim 14, further comprising a molding member covering the conductive wires.

16. The semiconductor module of claim 12, further comprising first conductive members mounted on the first lands and the pads.

17. The semiconductor module of claim 16, further comprising a second semiconductor package stacked on the first conductive members.

18. The semiconductor module of claim 12, further comprising second conductive members mounted on the second lands.

19. The semiconductor module of claim 12, wherein the second bond fingers are arranged at edge portions of a bottom surface of the cavity and make direct contact with the first bond fingers.

20. The semiconductor module of claim 10, wherein the semiconductor package comprises:
a semiconductor chip;
an insulating substrate attached on the semiconductor chip;
the first bond fingers arranged on edge portions of an upper surface of the insulating substrate and electrically connecting the semiconductor chip with the circuit pattern; and
the pads arranged on a central portion of the upper surface of the insulating substrate, the pads electrically connected to the first bond fingers.

21. The semiconductor module of claim 20, wherein the semiconductor package further comprises:
an auxiliary insulating substrate attached to a lower surface of the semiconductor chip; and
auxiliary bond fingers arranged on edge portions of a lower surface of the auxiliary insulating substrate, the auxiliary bond fingers electrically connected to the first bond fingers and making direct contact with the circuit pattern.

22. A semiconductor module comprising:
a circuit substrate having a cavity and a circuit pattern; and
a semiconductor package arranged in the cavity,
wherein the semiconductor package includes:
a semiconductor chip;
an insulating substrate attached to the semiconductor chip;
first bond fingers arranged on edge portions of an upper surface of the insulating substrate and electrically connecting the semiconductor chip with the circuit pattern; and
pads arranged on a central portion of the upper surface of the insulating substrate, the pads electrically connected to the first bond fingers, and
wherein the circuit pattern includes:
second bond fingers arranged on the circuit substrate, the second bond fingers electrically connected to the first bond fingers;
first lands arranged on an upper surface of the circuit substrate, the first lands electrically connected to the second bond fingers; and
second lands arranged on a lower surface of the circuit substrate, the second lands electrically connected to the second bond fingers.

23. The semiconductor module of claim 22, further comprising:
conductive wires electrically connecting the first bond fingers to the second bond fingers; and
a molding member covering the conductive wires.

24. A semiconductor module comprising:
a circuit substrate having a cavity and a circuit pattern; and
a semiconductor package arranged in the cavity,
wherein the semiconductor package includes:
a semiconductor chip;
an insulating substrate attached to the semiconductor chip;
first bond fingers arranged on edge portions of an upper surface of the insulating substrate and electrically connecting the semiconductor chip with the circuit pattern;
pads arranged on a central portion of the upper surface of the insulating substrate, the pads electrically connected to the first bond fingers;
an auxiliary insulating substrate attached to a lower surface of the semiconductor chip; and
auxiliary bond fingers arranged on edge portions of a lower surface of the auxiliary insulating substrate, the auxiliary bond fingers electrically connected to the first bond fingers and making direct contact with the second bond fingers, and
wherein the circuit pattern includes:
second bond fingers arranged on the circuit substrate, the second bond fingers electrically connected to the first bond fingers;
first lands arranged on an upper surface of the circuit substrate, the first lands electrically connected to the second bond fingers; and
second lands arranged on a lower surface of the circuit substrate, the second lands electrically connected to the second bond fingers.
